(19) United States
(12) Patent Application Publication
(10) Pub. No.: US 2025/0126742 A1
(43) Pub. Date: Apr. 17, 2025

(54) Estimating ambient airflow based on temperature sensing

(71) Applicant: MELLANOX TECHNOLOGIES, LTD., Yokneam (IL)

(72) Inventors: Adi Yekutiel, Adi (IL); Haim Kupershmidt, Or Yehuda (IL)

(21) Appl. No.: 18/485,368

(22) Filed: Oct. 12, 2023

(51) Int. Cl. H05K 7/20

(52) U.S. Cl. CPC H05K 7/20209; H05K 7/20154

(57) ABSTRACT

An apparatus includes an interface and a processor. The interface is configured to receive measurements of a first temperature of an integrated circuit (IC), and a second temperature of air in a case that surrounds the IC. The processor is configured to: (a) estimate a thermal resistance between the IC and the air, and (b) estimate, based on (i) the thermal resistance between the IC and the air, and (ii) the first and second temperatures, a flow rate of the air flowing through the case for dissipating heat generated by the IC.

### FIELD OF THE INVENTION

The present invention relates generally to management of heat generated in electronic systems, and particularly to techniques for estimating ambient airflow based on temperature sensing.

### BACKGROUND OF THE INVENTION

Electronic systems include integrated circuits (IC) devices that generate heat while being operated. Various techniques for dissipating the heat, such as flowing air through the system, are known in the art. In such systems, it is important to estimate the flow rate of the air so as to control the heat dissipation.

### SUMMARY OF THE INVENTION

An embodiment of the present invention that is described herein provides an apparatus including an interface and a processor. The interface is configured to receive measurements of a first temperature of an integrated circuit (IC), and a second temperature of air in a case that surrounds the IC. The processor is configured to: (a) estimate a thermal resistance between the IC and the air, and (b) estimate, based on (i) the thermal resistance between the IC and the air, and (ii) the first and second temperatures, a flow rate of the air flowing through the case for dissipating heat generated by the IC.

In some embodiments, a heatsink (HS) is disposed on the IC, the interface is configured to receive a third temperature of the HS, and the processor is configured to: (i) hold or receive a parameter indicative of a first thermal resistance between the IC and the HS, and (ii) estimate a second thermal resistance, between the HS and the air, based on: (a) the first thermal resistance, and (b) the first, second and third temperatures.

In other embodiments, the processor is configured to estimate the flow rate of the air based on the estimated second thermal resistance between the HS and the air.

In yet other embodiments, the IC is mounted on a substrate, the thermal resistance between the IC and the air is a combination of (1) the first and second thermal resistances, and (2) a third thermal resistance between the IC and the substrate, the interface is configured to receive a fourth temperature of the substrate, and the processor is configured to: (i) hold or receive an additional parameter indicative of the third thermal resistance, and (ii) estimate the second thermal resistance between the HS and the air, based on: (a) the first and third thermal resistances, and (b) the first, second and fourth temperatures.

In some embodiments, the parameter and the additional parameter are pre-characterized based on: (i) properties of materials of the HS and the substrate, and (ii) a structure including at least the substrate, the IC, and the HS. In other embodiments, at least one of the first temperature, the second temperature, and the third temperature is obtained in a steady state condition. In yet other embodiments, the processor is configured to estimate the flow rate of the air based on a pre-characterized dependency between the second thermal resistance and the flow rate of the air.

In some embodiments, the apparatus includes a cooling device configured to flow the air, and based on the estimated flow rate, the processor is configured to control the cooling device to match the estimated flow rate to a desired flow rate of the air flowing through the case.

In other embodiments, the apparatus includes a first temperature sensor configured to measure the first temperature, and one or more second temperature sensors disposed within the case and configured to measure the second temperature, the case has first and second openings for flowing the air into the case through the first opening and drawing the air out of the case through the second opening, and the one or more second temperature sensors include: (i) a first ambient temperature sensor configured to generate a first ambient temperature measurement of the air flowing into the case, and (ii) a second ambient temperature sensor configured to generate a second ambient temperature measurement of the air flowing out of the case.

In yet other embodiments, the processor is configured to estimate the second temperature based on the first and second ambient temperature measurements.

There is additionally provided, in accordance with an embodiment of the present invention, a method including receiving measurements of a first temperature of an integrated circuit (IC), and a second temperature of air in a case that surrounds the IC. A thermal resistance between the IC and the air is estimated. Based on (i) the thermal resistance between the IC and the air, and (ii) the first and second temperatures, a flow rate of the air, which is flowing through the case for dissipating heat generated by the IC, is estimated.

The present invention will be more fully understood from the following detailed description of the embodiments thereof, taken together with the drawings in which:

### BRIEF DESCRIPTION OF THE DRAWINGS

FIG. 1 is a schematic, pictorial illustration of an electronic system, in accordance with an embodiment of the present invention;

FIG. 2 is a block diagram indicative of a model for estimating flow rate of air for cooling the electronic system of FIG. 1 based on thermal resistance between an integrated circuit (IC) and ambient air in the electronic system, in accordance with an embodiment of the present invention;

FIG. 3 is a block diagram indicative of another model for estimating flow rate of air for cooling the electronic system of FIG. 1, in accordance with another embodiment of the present invention;

FIG. 4 is a flow chart that schematically illustrates a method for estimating flow rate of air for cooling the electronic system of FIG. 1, in accordance with an embodiment of the present invention; and

FIG. 5 is a flow chart that schematically illustrates a method for estimating flow rate of air for cooling the electronic system of FIG. 1, in accordance with another embodiment of the present invention.

### DETAILED DESCRIPTION OF EMBODIMENTS

### Overview

Electronic systems, such as high-performance computing (HPC) systems and data centers, typically comprise one or more electronic devices, such as application-specific integrated circuits (ASICS), processors, and memory devices. The electronic devices are typically mounted (or stacked) on a circuit board (CB) or on one or more other suitable substrates, and are configured to receive power from the CB, and to exchange signals with the CB and/or with one another.

Such electronic devices generate heat while being operated. Excess heat may reduce the functionality of the system, its reliability and useful lifetime, and in severe cases, may burn out one or more of the electronic devices and/or other components of the electronic system.

Various techniques have been developed for dissipating the heat generated by the electronic devices. For example, using heatsinks and/or flowing air or fluids to transfer the generated heat away from the respective electronic devices. Moreover, one or more temperature sensors are implemented in the system (e.g., within the devices, in the ambience surrounding the devices, and elsewhere as will be described in detail below) in order to monitor the temperature in predefined thermal zones of the system. In the context of the present disclosure, the term “thermal zone” and grammatical variations thereof refer to locations within the electronic system, whose temperatures are monitored using the signals received from the one or more temperature sensors described above.

In some cases, the electronic system may have areas whose temperature exceeds the thermal specification. Such areas are also referred to herein as hotspots, which may not be controlled sufficiently tightly by the thermal management of the system. For example, a limited number of temperature sensors, local thermal conditions, a failure in a temperature sensor and/or in a cooling device (e.g., a fan) of the system, may result in the generation of one or more hotspots.

Overheating of one or more components may reduce the electrical performance and the reliability of such electronic systems.

Embodiments of the present invention that are described hereinbelow provide techniques for improving the electrical performance and the reliability of electronic systems, such as but not limited to HPC systems and data centers.

In some embodiments, a simplified example of an electronic system comprises a substrate, such as a CB, an electronic device, such as an integrated circuit (IC) mounted on the CB, a heatsink (HS) coupled to the IC and configured to dissipate heat generated by the device, and a rack case encapsulating the CB, IC, and HS.

In some embodiment, the electronic system comprises a thermal management apparatus configured to monitor the temperatures at predefined thermal zones within the system. The thermal management apparatus is further configured to prevent the formation of hotspots, e.g., by controlling the operation of cooling devices, such as fans, for dissipating the heat generated at the thermal zones, and more specifically at the hotspots.

In some embodiments, the thermal management apparatus comprises temperature sensors coupled to or implemented within the: (i) CB, (ii) IC, (iii) HS, and (iv) one or more locations in the ambience (typically air) surrounding the IC within the rack case. The thermal management apparatus further comprises cooling devices, such as fans configured to blow the air into and out of the rack case.

In principle, it is possible to measure the flow rate of the air, for example, using any suitable type of one or more air flow sensors mounted on the CB. However, such air flow sensors increase the cost of the system and occupy valuable real estate of the CB, which cannot be used for operating the components of the system. Thus, a solution for estimating the flow rate without air flow sensors is required.

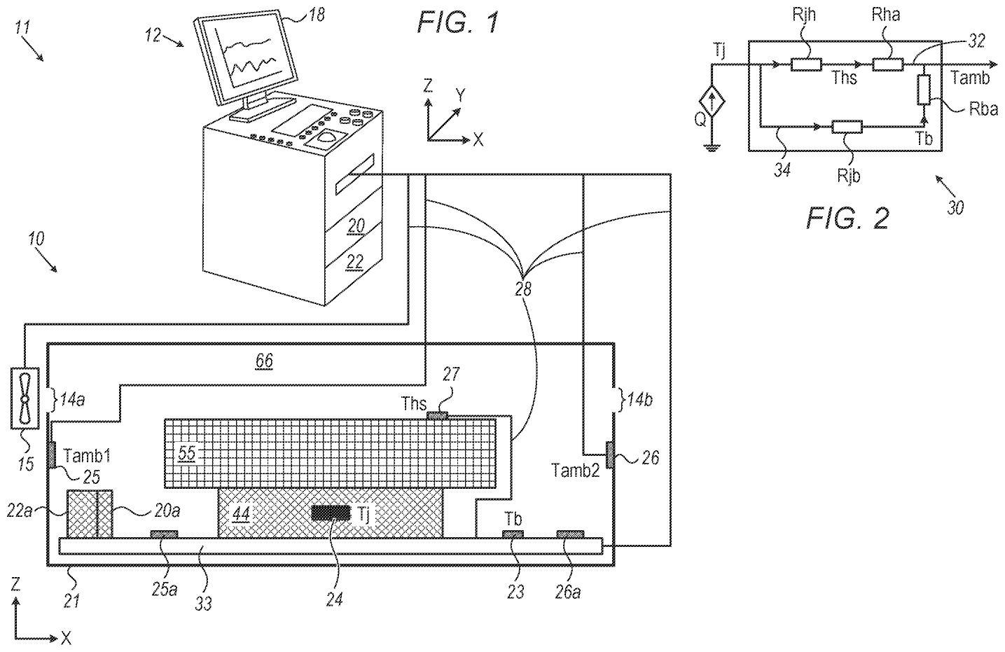

In some embodiment, the thermal management apparatus comprises an interface configured to receive from the temperature sensors, signals indicative of the temperature reads. The thermal management apparatus further comprises which is configured to estimate thermal a processor, resistance for transferring the heat from the IC to the air of the ambience, as will be described in detail in FIGS. 1-3 below. Moreover, based on (i) the estimated thermal resistance, and (ii) temperature readings of at least the IC and the ambience, the processor is configured to estimate the flow rate of the ambient air flowing through the rack case in order to dissipate the heat generated by the IC. The above embodiments are further described in the detailed description below.

In some embodiment, the thermal management apparatus comprises an additional processor (or any suitable type of a controller) configured to operate the cooling devices. Based on the above estimations, the additional processor is configured to control the cooling device (e.g., one or more fans) to adjust the flow rate of the air to a desired flow rate in order to dissipate the excess heat generated by the IC, and thereby, to reduce the hotspots in the electronic devices.

In an example configuration, the processor may be mounted on the CB and configured to provide warnings and/or indications, and the additional processor is implemented in a console, such as a hardware management console (HMC) or a baseboard management controller (BMC). In this configuration, the additional processor is configured to receive the estimated flow rate from the processor (e.g., via the CB), and to activate the cooling devices based on these warnings and/or indications received from the processor. This configuration is described in detail in FIG. 1 below.

In other embodiments, in addition to estimating the flow rate (as described above), the processor is further configured to control the operation of the cooling devices (e.g., instead of the additional processor).

The disclosed techniques improve the thermal control, and thereby, the performance and reliability of electronic systems, such as but not limited to HPC systems and data centers.

### System Description

FIG. 1 is a schematic, pictorial illustration of an electronic system 10, in accordance with an embodiment of the present invention.

In some embodiments, electronic system 10 comprises a substrate, in the present example a circuit board (CB) 33, and one or more electronic devices, such as an electronic device implemented in an integrated circuit (IC) 44, which is mounted on CB 33 and is configured to receive power from CB 33, and to exchange data signals with CB 33, and optionally with other ICs mounted on SB 33. It is noted that while being operated, IC 44 generates heat that must be dissipated in order to enable the operation and the specified functionality of electronic system 10.

In some embodiments, electronic system 10 comprises a heatsink (HS) 55, which is coupled to IC 44 and is configured to dissipate the heat generated by IC 44. Electronic system 10 further comprises a rack case, also referred to herein as a case 21 (for brevity and generalization), which is configured to: (i) encapsulate CB 33, IC 44, and HS 55, and (ii) contain air 66 (or any other suitable gas) in the ambience within the volume surrounded by case 21. In the present example, case 21 has two openings 14a and 14b, which are configured to allow the flowing of air 66 through case 21. In other embodiments, the configuration of case 21 may have any other suitable configurations of openings 14a and 14b and/or other suitable techniques for allowing the flowing of air 66.

Moreover, system 10 comprises one or more cooling devices, in the present example a fan 15, which is configured to push air 66 into the volume of case 21 and/or to draw air 66 out of the volume of case 21 in order to move air 66 through case 21, and thereby, to dissipate the heat generated by IC 44.

In some embodiments, system 10 comprises a thermal management apparatus, referred to herein as an apparatus 11 that among other capabilities, is configured to estimate the flow rate of air 66 through case 21 for dissipating the heat generated by IC 44.

In some embodiments, apparatus 11 comprises multiple temperature sensors, more specifically: (i) a temperature sensor 23, which is coupled to or implemented within CB 33, and is configured to generate a signal indicative of the temperature of CB 33, referred to herein as Tb, (ii) a temperature sensor 24, which is coupled to or implemented within IC 44, and is configured to generate a signal indicative of the temperature of IC 44, referred to herein as Tj, (iii) one or more ambient temperature sensors, in the present example two sensors 25 and 26 that are mounted on case 21 (but are typically thermally insulated from case 21) at two different locations (e.g., in proximity to openings 14a and 14b, respectively). The functionality of sensors 25 and 26 is described below.

In other embodiments, CB 33 and the devices mounted thereon serve as a product which is integrated in a system supplied by another entity (e.g., another supplier). In such embodiments, instead of or in addition to sensors 25 and 26, one or more ambient temperature sensors 25a and 26a may be mounted on CB 33. As will be described in detail below, ambient temperature sensors 25a and 26a are configured to generate signals indicative of the ambient temperatures of air 66, also referred to herein as Tamb1 and Tamb2, respectively. As such, the one or more ambient temperature sensors 25a and 26a (that are mounted on CB 33) must be thermally insulated so that the temperature readings (provided by ambient temperature sensors 25a and 26a) are indicative of the temperature of air 66 and are not affected by the temperature of CB 33 (which is being measured using temperature sensor 23, as described above).

In alternative embodiments, apparatus 11 may comprise any other suitable number (i.e., one or more) of ambient temperature sensors mounted at one or more suitable respective positions.

In the context of the present disclosure and in the claims, the term temperature sensor “coupled to” a device, refers to any suitable type of coupling between the temperature sensor and the respective device, such as but not limited to mounting on, embedded within, integrated with, bonded to, soldered to, and even non-contact temperature sensing, e.g., based on infrared sensing.

Moreover, in some cases the coupling may allow thermal coupling between the sensor and the respective device, and in other cases a sensor may be coupled to a device of system 10, but may be thermally insulated from that device. For example, temperature sensors 25 and 26 may be mounted on case 21, but are thermally insulated from case 21 in order to measure the temperature of air 66 flowing through case 21.

In some embodiments, the ambient temperature sensors are thermally insulated from case 21, so as to generate temperature readings of the ambience rather than of case 21.

In the present configuration, sensors 25 and 26 are configured to generate signals indicative of the ambient temperatures of air 66, referred to herein as Tamb1 and Tamb2, respectively, and (iv) a temperature sensor 27 coupled to HS 55, and configured to generate a signal indicative of the temperature of HS 55, referred to herein as Ths.

In some embodiment, apparatus 11 comprises a control console, also referred to herein as a hardware management console (HMC), or a baseboard management controller (BMC), or a console 12, for brevity.

It is noted that for the sake of conceptual clarity, console 12 is shown in a schematic three-dimensional (3D) pictorial presentation of an XYZ coordinate system, and the other components of FIG. 1 are presented in a sectional view of an XZ plane of the XYZ coordinate system.

In some embodiments, system 10 and apparatus 11 comprise an interface 20a and a processor 22a, which are mounted on CB 33. In the example configuration shown in FIG. 1, temperature sensors 23, 25a and 26a, are electrically connected to CB 33, temperature sensor 27 is connected to CB 33 via a cable 28 or any suitable electrical traces, and temperature sensor 24 is connected to CB 33 via IC 44.

In some embodiments, interface 20a is configured to receive from temperature sensors 23, 24, 25a, 26a and 27, the aforementioned signals indicative of the temperature reads of Tb, Tj, Tamb1, Tamb2 and Ths, respectively. In the present t example, interface 20a and processor 22a are separate devices, but in alternative embodiments, processor 22a and interface 20a may be implemented in a single common device, and may have one or more heatsinks mounted thereon for dissipating the heat generated by processor 22a. Additionally, or alternatively, IC 44 is configured to fulfill the functions of both interface 20a and processor 22a, which are described in detail below. As such, the signals indicative of the temperature readings are sent from temperature sensors 23, 25a, 26a and 27 to IC 44, and the signal from sensor 24 is being conducted within the circuits of IC 44.

Moreover, in this configuration temperature sensors 25 and 26 may be connected to CB 33 or to console 12, via cables 28 or using any other suitable wiring or wireless components (not shown). In such embodiments, the signals produced by temperature sensors 23, 25a, 26a and 27 are typically conducted to interface 20a (or to IC 44) via the electrically conductive traces (not shown) of CB 33, as described above.

In some embodiments, apparatus 11 may comprise a display 18 configured to display graphs of the temperature reads and estimated airflow, as well as any other suitable information.

In the present example, display 18 is implemented in console 12, but may alternatively be implemented in any other computer integrated in or connected to system 10.

In some embodiments, system 10 comprise cables 28 configured to exchange signals between (i) CB 33 and console 12, and (ii) console 12 and fan 15 for controlling the rotation direction and speed of fan 15, as will be described in detail below.

In the present example, the communication between console 12 and CB 33 is based on suitable protocols known in the art, such as Platform Level Data Model (PLDM) or Network Controller Sideband Interface (NC-SI).

It is noted that the flow of air 66 through case 21 (e.g., between openings 14a and 14b) may be one-directional or bi-directional, and the flow rate of air 66 determines the dissipation rate of the heat generated by IC 44. Thus, it is important to estimate the actual flow rate of air 66 within case 21.

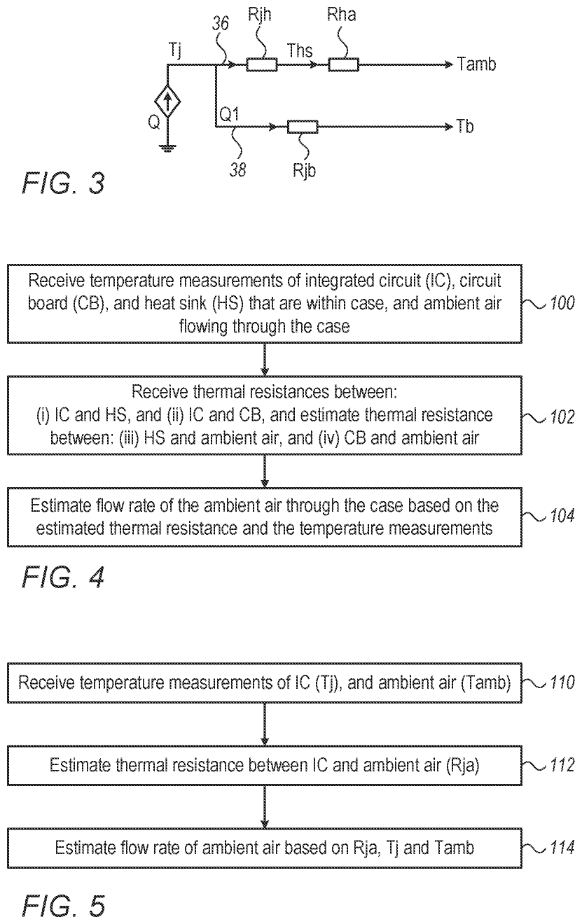

In some embodiment, based on: (i) pre-characterization of thermal resistance between IC 44 and HS 55, and between IC 44 and CB 33 (as will be described below), and (ii) the signals received from the temperature sensors, e.g., from sensors 23, 24, 25a (and/or 25), 26a (and/or 26) and 27, processor 22a (and/or IC 44) is configured to estimate the thermal resistance for transferring the heat between: at least one of (i) IC 44 and air 66, and (ii) HS 55 and air 66. It is noted that the thermal resistance to the heat transfer comprises several components and at least the thermal resistance between HS 55 and air 66 depends on the flow rate of air 66, as will be described in detail in FIGS. 2 and 3 below.

In some embodiments, based on (i) the estimated thermal resistance, and (ii) the temperature readings received from at least sensors 24-26, processor 22a (or IC 44) is configured to estimate the flow rate of the air 66 flowing through case 21 in order to dissipate the heat generated by IC 44. It is noted that estimating the flow rate of air 66 by processor 22a or IC 44 reduces the need to directly measure the flow rate of air 66.

In some embodiments, console 12 comprises an interface 20 configured to receive from CB 33 the flow rate of air 66, which is estimated by at least one of processor 22a and IC 44. Console 12 further comprises a processor 22 that, based on the received estimated flow rate, is configured to control fan 15 (and if applicable, any other cooling devices of system 10) in order to control the temperature of at least IC 44. In the present configuration, the controlled temperature of IC 44 is obtained using a desired flow rate of air 66 flowing through case 21 in order to dissipate at least some of the heat generated by IC 44. In the context of the present disclosure and in the claims, the term “desired flow rate” refers to a flow rate of air 66 that would provide sufficient cooling for dissipating heat generated by IC 44 and preventing overheating of IC 44 and other components of system 10.

In the present example, processor 22 is configured to control the rotation speed of fan 15 to adjust the estimated flow rate of air 66 through case 21. Subsequently, the flow rate is estimated by processor 22a and/or IC 44, and this iterative process repeats until the estimated flow rate is matched to the desired flow rate of air 66.

In alternative embodiments, processor 20 is configured to receive the temperature signals and estimate the flow rate (instead of or in addition to at least one of processor 22a and IC 44). In yet other embodiments, at least one of processor 22a and IC 44 are configured to control fan 15 to match the estimated flow rate of air 66 to the aforementioned desired flow rate described above.

FIG. 2 is a block diagram indicative of a model for estimating flow rate of air 66 for cooling IC 44 based on a thermal resistance 30 between IC 44 and air 66 of the ambient, in accordance with an embodiment of the present invention.

In some embodiments, the heat flowing through the components of system 10 can be modeled as an equivalent electrical circuit as depicted in FIG. 2. As such, the heat flow is modeled by an electrical current, the temperature is modeled by an electrical voltage, and the heat flow resistances (at interfaces between adjacent components of system 10) are modeled by electrical resistors.

In some embodiments, the model assumes that all the power supplied to IC 44 (e.g., by CB 33) is turned into heat flowing out of IC 44, and the heat is dissipated over time through channels described in FIGS. 2 and 3 below. For example, the level of power may be estimated based on voltage and current measurements and/or by the activity load of IC 44. As such, IC 44 serves as a heat generator “Q,” whose temperature is denoted Tj, as described in FIG. 1 above.

In some embodiments, the model of FIG. 2 comprises two channels 32 and 34. Channel 32 models the heat flow through HS 55, and channel 34 models the heat flow through CB 33.

In the present example, the model is an approximation and considers only the most significant mechanisms of heat dissipation, by conduction through (i) HS 55 on one side, and (ii) CB 33 on the other side, both along the Z-axis.

In other examples, in addition to the heat dissipation approximation along the Z-axis, the model may incorporate other heat transfer mechanisms, such as but not limited to radiation, and/or transfer of at least a portion of the heat along the X- and Y-axes.

In some embodiments, the model has parameters that are indicative of thermal resistance to the heat flowing between hotter and colder components of system 10, these parameters are described herein.

In some embodiments, channel 32 comprises: (i) an Rjh, which is a parameter of the model that is indicative of the thermal resistance to the heat flowing between IC 44 and HS 55, (ii) Ths, which is a parameter of the model that is indicative of the temperature of HS 55 (e.g., measured by sensor 27 as described in FIG. 1 above), and (iii) an Rha, which is a parameter of the model that is indicative of the thermal resistance to the heat flowing between HS 55 and air 66 of the ambience within case 21.

In some embodiments, channel 34 comprises: (i) an Rjb, which is a parameter of the model that is indicative of the thermal resistance to the heat flowing between IC 44 and CB 33, (ii) Tb, which is a parameter of the model that is indicative of the temperature of CB 33 (e.g., measured by sensor 23 as described in FIG. 1 above), and (iii) an Rba, which is a parameter of the model that is indicative of the thermal resistance to the heat flowing between CB 33 and air 66 of the ambience within case 21.

In some embodiments, thermal resistance 30, also referred to herein as Rja (thermal resistance between IC 44 and air 66 of the ambience), is a parameter of the model that is indicative of thermal resistance equivalent to the overall thermal resistances between IC 44 and the ambient air 66.

In some embodiments, the estimation of parameters Rjh and Rjb may be pre-characterized using a suitable setup indicative of the structure of system 10, and based on the properties (e.g., thermal conductivity of the materials) of HS 55, CB 33 and of thermal interface material (TIM) that may be disposed between IC 44 and each of HS 55 and CB 33. It is noted that Rha depends on (i) the flow rate of air 66, (ii) the temperature of the ambient air 66 (Tamb), which are the main factors, and also (iii) based on the temperature of IC 44 (Tj). By characterizing this dependence for a specific system, a model of Rha function Rha=f(Tamb, Airflow, Tj) can be built. Based on such a model, the airflow can be estimated when all other parameters are given, by reversing the above dependency: Airflow=f(Rha, Tamb, Tj).

As will be described below, in the example model of FIG. 2, the estimation of Rja and the flow rate of air 66 are based on signals received from (i) temperature sensor 24 (indicative of the Tj), and (ii) one or more ambient temperature sensors, such as sensors 25a and 26a. As such, the Ths and the Tb are not required for the estimation of Rja and the flow rate of air 66. It is noted that the model of FIG. 2 reduces the need to include one or both of the sensors 23 and 27 (or at least the temperature readings therefrom) in the configuration of apparatus 11.

In some embodiments, the term “Tamb” in FIG. 2 refers to the ambient temperature of air 66 within case 21. In an embodiment, Tamb may be calculated as the minimal temperature among Tamb1 and Tamb2 described in FIG. 1 above. In another embodiment, Tamb may be calculated by averaging between Tamb1 and Tamb2. The same calculations of the above options are applicable in case apparatus 11 comprises three or more ambient temperature sensors. Additionally, or alternatively, processor 22a and/or IC 44 may use any other suitable empirically derived function of the ambient measurements, including corrections for non-ideal isolation from CB 33 and/or from case 21.

In alternative embodiments, in case apparatus 11 comprises a single ambient temperature sensor (as described in FIG. 1 above), then Tamb comprises the temperature readings provided solely by the ambient temperature sensor.

In some embodiments, a simplified model of the heat flowing in steady state (based on the analogy of Ohm's law, and in accordance with a criterion described below)) is provided in an equation (i):

$$T j - T a m b = Q * R j a \qquad ( i )$$

Wherein Rja denotes thermal resistance 30, which is described above.

By dividing both sides of equation (i) by Q, at least one of processor 22a and IC 44 is configured to estimate the value of Rja by using an equation (ii):

$$Rja = ( T j - T a mb ) / Q \qquad ( ii )$$

In some embodiments, thermal resistance 30, e.g., the estimated value of Rja, depends on the flow rate of air 66 through case 21.

In such embodiments, at least one of processor 22a and IC 44 is configured to estimate the flow rate of air 66 based on the estimated value of Rja.

It is noted that in the example model of FIG. 2, the estimation of Rja and the flow rate of air 66 are based on signals received from (i) temperature sensor 24 (indicative of the Tj), and (ii) one or more ambient temperature sensors, such as sensors 25a and 26a. As such, at least one of sensors 23 and 27 may be omitted from the configuration of system 10, so as to: (a) obtain more real estate in CB 33, and (b) simplify the configuration and reduce the cost of system 10.

Additionally, or alternatively, system 10 and apparatus 11 may comprise at least one of sensors 23 and 27, but processor 22a and/or IC 44 may not need to use signals indicative of the Tb and Ths, as described above.

It is noted that the model of FIG. 2 is simplified and provided by way of example, in order to illustrate certain problems related to thermal management and configuration of the electronic system that are addressed by embodiments of the present invention and to demonstrate the application of these embodiments in enhancing the performance of such an electronic system. Embodiments of the present invention, however, are by no means limited to this specific sort of example model, and the principles described herein may similarly be applied to other sorts of models and electronic systems.

FIG. 3 is a block diagram indicative of another model for estimating the flow rate of air 66 for cooling IC 44, in accordance with another embodiment of the present invention.

In some embodiments, apparatus 11 comprises all the temperature sensors described in FIG. 1 above, including sensors 23 and 27. Moreover, the ambient temperature (Tamb) is calculated based on either (i) the minimal ambient temperature among Tamb1 and Tamb2, or (ii) averaging between Tamb1 and Tamb2, as described in FIG. 2 above, or (iii) another function, possibly including empirical corrections due to non-ideal decoupling of one or more of the temperature sensors from CB 33 and/or from case 21.

In some embodiments, in the model of FIG. 3, (i) a channel 38 is indicative of a heat Q1, which is a portion of the heat Q that is generated by IC 44 (as described in detail in FIG. 2 above), and the generated heat flows through CB 33, and (ii) a channel 36 is indicative of the remaining of the generated heat (Q-Q1) that flows through HS 55.

In some embodiments, a simplified model of the heat flowing through CB 33 in steady state is provided in an equation (iii):

$$Tj - T b = Q 1 * R j b \qquad ( iii )$$

Wherein Rjb denotes the thermal resistance to the heat flowing between IC 44 and CB 33, as described above.

Moreover, a simplified model of the heat flowing through HS 55 in steady state is provided in an equation (iv):

$$T j - T a m b = ( Q - Q 1 ) * ( R j h + R h a ) \qquad ( iv )$$

Wherein:
Rjb denotes the thermal resistance to the heat flowing between IC 44 and HS 55, as described above, and
Rha denotes the thermal resistance to the heat flowing between HS 55 and air 66 of the ambience within case 21, as described above.

It is noted that the model of FIG. 3 requires Tb, which is the temperature measured on CB 33 using temperature sensor 23.

Based on equations (iii) and (iv), processor 22 is configured to estimate the value of Rha using an equation (v):

$$R h a = \frac{R j b * ( T j - T a m b )}{Q * R j b - T j + T b} - R j h \qquad ( v )$$

It is noted that the estimated value of Rha (the resistance to heat transfer between HS 55 and air 66 of the ambience within case 21) depends on the flow rate of air 66 through case 21.

In some embodiments, at least one of processor 22a and IC 44 is configured to estimate the flow rate of air 66 based on the estimated value of Rha.

In other embodiments, at least one of processor 22a and IC 44 is configured to estimate Rha by applying the analogy of Ohm's law to the model of channel 36. In such embodiments, the model assumes that in steady state, an equal level of heat flows: (i) between IC 44 and HS 55, and (ii) between HS 55 and air 66. In the context of the present disclosure and in the claims, the terms “steady state” and “steady state condition” refer to any suitable criterion, for example, the temperature reads being within a predefined range of temperature change (e.g., between about −30° C. and +30° C.), and within a predefined time interval (e.g., between about 10 second and 30 seconds).

As such, the equal level of heat flow is provided in an equation (vi):

$$\frac{T h s - T j}{R j h} = \frac{T a m b - T h s}{R h a} \qquad ( vi )$$

In some embodiments, based on equation (vi) at least one of processor 22a and IC 44 is configured to estimate the heat flow resistance between HS 55 and air 66 (i.e., Rha), which is provided by an equation (vii):

$$Rha = \frac{R j h * ( T a m b - T h s )}{T h s - T j} \qquad ( vii )$$

In some embodiments, at least one of processor 22a and IC 44 is configured to hold a function, which is indicative of the dependency between Rha and the flow rate of air 66. This function may be based on pre-characterized empirical data (e.g., a graph of the value of Rha and the flow rate), or based on any other suitable model. In such embodiments, at least one of processor 22a and IC 44 is configured to estimate the flow rate of air 66 based on the estimated value of Rha.

In some embodiments, based on the measured temperatures and the estimated flow rate of air 66 (using one or more of the techniques described in FIGS. 2 and 3 above), processor 22 is configured to control fan 15 to adjust the flow rate of air 66.

In other embodiments, in case of a failure to adjust the flow rate of air 66, e.g., due to a failure in fan 15 or for any other reason, processor 22 is configured to provide the operator of system 10 with an alarm of at least one of: (i) overheating of at least one of IC 44, CB 33, and HS 55, and (ii) a requirement and/or a failure to adjust the flow rate of air 66.

Based on the embodiments described above, processor 22 is configured to provide the operator of system 10 with the thermal status of system 10, and more specifically, with indications of (i) exceeding temperature(s) in one or more components of system 10, and (ii) incorrect flow rate of air 66 within case 21.

FIG. 4 is a flow chart that schematically illustrates a method for estimating the flow rate of air 66 for cooling electronic system 10, in accordance with an embodiment of the present invention.

The method begins at a temperature receiving step 100, with interface 20 receiving temperature measurements of: IC 44 (Tj), CB 33 (Tb), HS 55 (Ths), which are located within case 21, and of ambient air 66 (Tamb1 and Tamb2) flowing through case 21, as described in detail in FIG. 1 above. In embodiments, some all the temperature measurements are acquired in steady state conditions, such as the conditions defined in the description of FIG. 3 above.

In other embodiments, interface 20 receives only Tj, Tamb1 and Tamb2, as described in detail in FIGS. 1 and 2 above.

At a thermal resistance estimation step 102, at least one of processor 22a and IC 44 holds or receives parameters indicative of the thermal resistances between (i) IC 44 and HS 55 (Rjh), and (ii) IC 44 and CB 33 (Rjb). Moreover, based on the parameters of step 102, pre-characterization of some of the thermal resistances (e.g., Rjh and Rjb), and the temperature measurements of step 100, at least one of processor 22a and IC 44 estimates the thermal resistance between: (iii) HS 55 and air 66 (Rha), and (iv) CB 33 and air 66 (Rba), as described in detail in FIG. 3 above.

In other embodiments, at least one of processor 22a and IC 44 is configured to estimate the thermal resistance between IC 44 and ambient air 66 (Rja) based on Tj, Tamb and the power supplied to IC 44, as also described in detail in FIG. 2 above.

At a flow rate estimation step 104 that concludes the method, at least one of processor 22a and IC 44 estimates the flow rate of air 66 through case 21 based on the estimated thermal resistances of step 102 above, and the temperature measurements of step 100 above, as described in detail in FIGS. 1 and 3 above.

In other embodiments, at least one of processor 22a and IC 44 estimates the flow rate of air 66 through case 21 based on: (i) the estimated thermal resistance Rja of step 102 above, and (ii) the temperature measurements, Tj, Tamb1 and Tamb2 of step 100 above, as described in detail in FIGS. 1 and 2 above.

Moreover, based on the embodiments described in the method and in more detail in FIG. 2 above, temperature sensors 23 and 27 may also be removed from the configuration of system 10 and apparatus 11, or alternatively, processor 22 may estimate the flow rate of air 66 without receiving Tb and Ths from sensors 23 and 27, respectively, as described in detail in FIG. 2 above.

FIG. 5 is a flow chart that schematically illustrates a method for estimating the flow rate of air 66 for cooling electronic system 10, in accordance with another embodiment of the present invention.

The method begins at a temperature measurement receiving step 110 with at least one of processor 22a (via interface 20a) and IC 44 receiving Tj (measured by sensor 24 of IC 44) and Tamb (calculated based on signals received from one or more of sensors 25, 25a, 26 and 26a), as described in detail in FIGS. 1 and 2 above.

At a thermal resistance estimation step 112, at least one of processor 22a and IC 44 estimates Rja, which is the thermal resistance for heat dissipation between IC 44 and ambient air 66, as described in detail at least in FIG. 2 above.

At a flow rate estimation step 114 that concludes the method, at least one of processor 22a and IC 44 is configured to estimate the flow rate of ambient air 66 based on (i) the estimated value of Rja (obtained in step 112 above), and (ii) the Tj and Tamb (obtained in step 110 above).

It will be appreciated that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. An apparatus, comprising:
an interface, to receive measurements of a first temperature of an integrated circuit (IC), and a second temperature of air in a case that surrounds the IC; and
a processer, to:
estimate a thermal resistance between the IC and the air; and
estimate, based on (i) the thermal resistance between the IC and the air, and (ii) the first and second temperatures, a flow rate of the air flowing through the case for dissipating heat generated by the IC.

2. The apparatus according to claim 1, wherein a heatsink (HS) is disposed on the IC, wherein the interface is to receive a third temperature of the HS, and wherein the processor is to: (i) hold or receive a parameter indicative of a first thermal resistance between the IC and the HS, and (ii) estimate a second thermal resistance, between the HS and the air, based on: (a) the first thermal resistance, and (b) the first, second and third temperatures.

3. The apparatus according to claim 2, wherein the processor is to estimate the flow rate of the air based on the estimated second thermal resistance between the HS and the air.

4. The apparatus according to claim 2, wherein the IC is mounted on a substrate, wherein the thermal resistance between the IC and the air is a combination of (1) the first and second thermal resistances, and (2) a third thermal resistance between the IC and the substrate, wherein the interface is to receive a fourth temperature of the substrate, and wherein the processor is to: (i) hold or receive an additional parameter indicative of the third thermal resistance, and (ii) estimate the second thermal resistance between the HS and the air, based on: (a) the first and third thermal resistances, and (b) the first, second and fourth temperatures.

5. The apparatus according to claim 4, wherein the parameter and the additional parameter are pre-characterized based on: (i) properties of materials of the HS and the substrate, and (ii) a structure comprising at least the substrate, the IC, and the HS.

6. The apparatus according to claim 2, wherein at least one of the first temperature, the second temperature, and the third temperature is obtained in a steady state condition.

7. The apparatus according to claim 2, wherein the processor is to estimate the flow rate of the air based on a pre-characterized dependency between the second thermal resistance and the flow rate of the air.

8. The apparatus according to claim 1, and comprising a cooling device to flow the air, and wherein, based on the estimated flow rate, the processor is to control the cooling device to match the estimated flow rate to a desired flow rate of the air flowing through the case.

9. The apparatus according to claim 1, and comprising a first temperature sensor to measure the first temperature, and one or more second temperature sensors disposed within the case to measure the second temperature, wherein the case has first and second openings for flowing the air into the case through the first opening and drawing the air out of the case through the second opening, and wherein the one or more second temperature sensors comprise: (i) a first ambient temperature sensor to generate a first ambient temperature measurement of the air flowing into the case, and (ii) a second ambient temperature sensor to generate a second ambient temperature measurement of the air flowing out of the case.

10. The apparatus according to claim 9, wherein the processor is to estimate the second temperature based on the first and second ambient temperature measurements.

11. A method, comprising:
receiving measurements of a first temperature of an integrated circuit (IC), and a second temperature of air in a case that surrounds the IC;
estimating a thermal resistance between the IC and the air; and
estimating, based on (i) the thermal resistance between the IC and the air, and (ii) the first and second temperatures, a flow rate of the air flowing through the case for dissipating heat generated by the IC.

12. The method according to claim 11, wherein a heatsink (HS) is disposed on the IC, and comprising (i) receiving a third temperature of the HS, (ii) holding or receiving a parameter indicative of a first thermal resistance between the IC and the HS, and (iii) estimating a second thermal resistance, between the HS and the air, based on: (a) the first thermal resistance, and (b) the first, second and third temperatures.

13. The method according to claim 12, wherein estimating the flow rate of the air is based on the estimated second thermal resistance between the HS and the air

14. The method according to claim 12, wherein the IC is mounted on a substrate, wherein the thermal resistance between the IC and the air is equivalent to a sum of (1) the first and second thermal resistances, and (2) a third thermal resistance between the IC and the substrate, and comprising: (i) receiving a fourth temperature of the substrate, (ii) holding or receiving an additional parameter indicative of the third thermal resistance, and (iii) estimating the second thermal resistance between the HS and the air, based on: (a) the first and third thermal resistances, and (b) the first, second and fourth temperatures.

15. The method according to claim 14, and comprising pre-characterizing the parameter and the additional parameter based on: (i) properties of materials of the HS and the substrate, and (ii) a structure comprising at least the substrate, the IC, and the HS.

16. The method according to claim 12, wherein at least one of the first temperature, the second temperature, and the third temperature is obtained in a steady state condition.

17. The method according to claim 12, wherein estimating the flow rate of the air is based on a pre-characterized dependency between the second thermal resistance and the flow rate of the air.

18. The method according to claim 11, and comprising a cooling device to flow the air, and comprising, based on the estimated flow rate, controlling the cooling device to match the estimated flow rate to a desired flow rate of the air flowing through the case.

19. The method according to claim 11, and comprising a first temperature sensor for measuring the first temperature, and one or more second temperature sensors disposed within the case for measuring the second temperature, wherein the case has first and second openings for flowing the air into the case through the first opening and drawing the air out of the case through the second opening, and wherein the one or more second temperature sensors comprise: (i) a first ambient temperature sensor for generating a first ambient temperature measurement of the air flowing into the case, and (ii) a second ambient temperature sensor for generating a second ambient temperature measurement of the air flowing out of the case.

20. The method according to claim 19, wherein estimating the second temperature is based on the first and second ambient temperature measurements.
